(19) United States
(12) Patent Application Publication
(10) Pub. No.: US 2025/0176074 A1
(43) Pub. Date: May 29, 2025

(54) CERAMIC HEATER

(71) Applicant: NGK INSULATORS, LTD., Nagoya-City (JP)

(72) Inventors: Yutaka UNNO, Handa-Shi (JP); Tomohiro HARA, Handa-Shi (JP)

(73) Assignee: NGK INSULATORS, LTD., Nagoya-City (JP)

(21) Appl. No.: 18/663,257

(22) Filed: May 14, 2024

Related U.S. Application Data
(63) Continuation of application No. PCT/JP2023/042379, filed on Nov. 27, 2023.

(51) Int. Cl. H05B 3/28

(52) U.S. Cl. CPC H05B 3/28

(57) ABSTRACT

There is provided a ceramic heater including a ceramic plate including an inner zone defined as a circular region within a predetermined distance from a center of the ceramic plate and an outer zone defined as an annular region outside the inner zone, an inner zone heater circuit embedded in the inner zone of the ceramic plate, an outer zone heater circuit embedded in the outer zone of the ceramic plate, and one pair of jumpers which are embedded in the inner zone of the ceramic plate so as not to contact the inner zone heater circuit and are electrically connected to the outer zone heater circuit. A percentage of a resistance value per jumper to a resistance value of the outer zone heater circuit is from 0.5 to 1.9%.

### CROSS-REFERENCE TO RELATED APPLICATION

This application is a continuation application of PCT/JP2023/042379 filed Nov. 27, 2023, the entire contents of which are incorporated herein by reference.

### BACKGROUND OF THE INVENTION

### 1. Field of the Invention

The present disclosure relates to a ceramic heater.

### 2. Description of the Related Art

In a deposition apparatus for a semiconductor manufacturing process, a ceramic heater is used as a support stage for controlling a temperature of a wafer such that the temperature is uniform. One including a ceramic plate on which a wafer is to be placed and a cylindrical ceramic shaft which is attached to the ceramic plate is widely used as such a ceramic heater. A multizone ceramic heater having a plurality of heating zones is also known as a ceramic heater.

Miniaturization and increase in the number of stacked layers for increase in the degree of semiconductor integration are progressing at an accelerating pace, and increase in the temperature of a semiconductor manufacturing process, increase in process time, and increase in plasma power are progressing. Along with this, more and more stringent demands are placed on ceramic heaters for thermal uniformity.

In a multizone ceramic heater with two or more zones including an inner zone heater circuit and an outer zone heater circuit, a member called a jumper is used to secure electrical connection from a feeding terminal near a center of a ceramic plate to the outer zone heater circuit. A jumper, however, is structurally likely to serve as a singularity in a temperature distribution and can become a factor in impairing thermal uniformity. For this reason, various measures have been presented for jumpers in terms of improving thermal uniformity. Examples of such measures include (1) the process of making a sectional area of a jumper larger than a sectional area of a heater (see Patent Literature 1 (to be described later)), (2) the process of shortening a length of a jumper by making the jumper as linear as possible (see Patent Literature 2 (to be described later)), and (3) the process of shortening a length of a jumper by reducing an area of an inner zone and increasing an area of an outer zone.

Patent Literature 1 (JP2018-537802A) discloses a substrate heating apparatus including a body portion which supports a substrate, a first heating element (inner zone heater circuit) which is located in an internal region of the body portion, a second heating element (outer zone heater circuit) which is located in an external region surrounding the internal region, and a third heating element (jumper) which transmits current to the second heating element across the internal region of the body portion. A diameter of a wire constituting the third heating element (jumper) is set larger than a diameter of a wire constituting the second heating element (outer zone heater circuit).

Patent Literature 2 (JP4640842B) discloses a heating apparatus including a heater and a hollow support member which is fixed to a back surface of the heater. The heater is one in which a first heating device, a second heating device, a first conductive connecting portion, a first terminal portion, a second conductive connecting portion, and a second terminal portion are embedded in a plate-shaped base made of an insulating material. While the first heating device is provided at a peripheral edge of the heater to form an outer zone heater circuit, the second heating device is provided at a central portion of the heater together with the first terminal portion, the second terminal portion, and the second conductive connecting portion to form an inner zone heater circuit. Respective first conductive connecting portions are connected to a plurality of end portions of the first heating device that corresponds to the outer zone heater circuit, and respective first terminal portions are connected to the first conductive connecting portions. Thus, each first conductive connecting portion corresponds to a jumper. The drawings of the literature disclose a circuit pattern in which a length of the first conductive connecting portion (jumper) is shortened by linearly constructing the first conductive connecting portion.

### CITATION LIST

### Patent Literature

Patent Literature 1: JP2018-537802A
Patent Literature 2: JP4640842B

### SUMMARY OF THE INVENTION

However, a conventional multizone ceramic heater including a jumper may suffer breakage at the time of manufacture or use. Even if this is not the case, the conventional multizone ceramic heater may suffer the problem of the inability to obtain desirable thermal uniformity or the problem of the difficulty in achieving a desirable temperature distribution profile when an inner zone/outer zone power ratio is changed.

The inventors have currently found that setting a percentage of a resistance value per jumper to a resistance value of an outer zone heater circuit within the range from 0.5 to 1.9% makes breakage unlikely to occur at the time of manufacture or use, and allows achievement of not only desirable thermal uniformity but also a desirable temperature distribution profile when an inner zone/outer zone a power ratio is changed.

Thus, an object of the present invention is to provide a multizone ceramic heater including a jumper which is unlikely to suffer breakage at the time of manufacture or use and is capable of achieving not only desirable thermal uniformity but also a desirable temperature distribution profile when an inner zone/outer zone power ratio is changed.

The present invention provides the following aspects.

### [Aspect 1]

A ceramic heater comprising:
a disk-shaped ceramic plate having a first surface on which a wafer is to be placed and a second surface opposite to the first surface, the ceramic plate including an inner zone defined as a circular region within a predetermined distance from a center of the ceramic plate and an outer zone defined as an annular region outside the inner zone when the ceramic plate is viewed in plan view;
an inner zone heater circuit embedded in the inner zone of the ceramic plate; an outer zone heater circuit embedded in the outer zone of the ceramic plate; and one pair of jumpers which are embedded in the inner zone of the ceramic plate so as not to contact the inner zone heater circuit and are electrically connected to the outer zone heater circuit,
wherein a percentage of a resistance value per the jumper to a resistance value of the outer zone heater circuit is from 0.5 to 1.9%.

### [Aspect 2]

The ceramic heater according to aspect 1, wherein the inner zone heater circuit and the outer zone heater circuit include a resistance heating element in the form of at least one selected from the group consisting of a coil, a linear zigzag structure, a printed pattern, a ribbon, and a mesh.

### [Aspect 3]

The ceramic heater according to aspect 2, wherein the outer zone heater circuit includes a resistance heating element in a coil form having a winding diameter of from 2.5 to 5.0 mm and a wire diameter of from 0.3 to 0.7 mm.

### [Aspect 4]

The ceramic heater according to aspect 2 or 3, wherein the outer zone heater circuit includes a resistance heating element in the form of a linear zigzag structure having a maximum width of from 5 to 15 mm and a wire diameter of from 0.3 to 0.7 mm.

### [Aspect 5]

The ceramic heater according to any one of aspects 1 to 4, wherein the jumpers include a resistance heating element in the form of at least one selected from the group consisting of a wire, a printed pattern, and a ribbon.

### [Aspect 6]

The ceramic heater according to any one of aspects 1 to 5, wherein the outer zone is divided into a plurality of outer subzones, and a sum of resistance values of the resistance heating element embedded in the plurality of outer subzones is regarded as the resistance value of the outer zone heater circuit.

### [Aspect 7]

The ceramic heater according to any one of aspects 1 to 6, wherein the ceramic plate contains aluminum nitride or aluminum oxide.

### [Aspect 8]

The ceramic heater according to any one of aspects 1 to 7, further comprising:
one pair of first feeding terminals for feeding power to the inner zone heater circuit which are provided in a central portion of the inner zone of the ceramic plate; and
one pair of second feeding terminals for feeding power to the outer zone heater circuit via the jumpers which are provided in the central portion of the inner zone of the ceramic plate.

### [Aspect 9]

The ceramic heater according to any one of aspects 1 to 8, further comprising an internal electrode which is an RF electrode and/or an ESC electrode in the ceramic plate.

### [Aspect 10]

The ceramic heater according to any one of aspects 1 to 9, further comprising a cylindrical ceramic shaft which is concentrically attached to the second surface of the ceramic plate and includes an internal space.

### BRIEF DESCRIPTION OF THE DRAWINGS

FIG. 1 is a transparent sectional view schematically showing one example of a ceramic heater according to the present invention. Note that a jumper 22 is drawn at a position slightly lower than an original position to clearly illustrate respective configurations of an inner zone control heater circuit 14a and the jumper 22 which are originally located at the same height, for convenience of description.

FIG. 2 is a top view schematically showing the ceramic heater shown in FIG. 1.

FIG. 3 is a transparent sectional view schematically showing another one example of the ceramic heater according to the present invention.

FIG. 4 is a top view schematically showing the ceramic heater shown in FIG. 3.

FIG. 5A is a plan view schematically showing circuit patterns of an inner zone heater circuit, an outer zone heater circuit, and jumpers adopted in Examples 1 to 9 and 12. Lines corresponding to the circuit patterns in FIG. 5A represent centerlines of the inner zone heater circuit, the outer zone heater circuit, and the jumpers.

FIG. 5B is a plan view schematically showing a circuit pattern of the inner zone heater circuit shown in FIG. 5A.

FIG. 5C is a plan view schematically showing a circuit pattern of the outer zone heater circuit and the jumpers shown in FIG. 5A.

FIG. 6A is a plan view schematically showing circuit patterns of an inner zone heater circuit, an outer zone heater circuit, and jumpers adopted in Examples 10 and 11. Lines corresponding to the circuit patterns in FIG. 6A represent centerlines of the inner zone heater circuit and the outer zone heater circuit.

FIG. 6B is a plan view schematically showing a circuit pattern of the inner zone heater circuit shown in FIG. 6A.

FIG. 6C is a plan view schematically showing a circuit pattern of the outer zone heater circuit and the jumpers shown in FIG. 6A.

FIG. 7 is a graph showing a relationship between a percentage of a resistance value per jumper to a resistance value of an outer zone heater circuit and an in-plane maximum temperature difference (thermal uniformity), which were measured in various types of examples including Examples 1 to 6.

FIG. 8 shows temperature profiles when outer/inner power ratios were changed to 1.4, which were measured in Examples 1 to 6.

### DETAILED DESCRIPTION OF THE INVENTION

A ceramic heater according to the present invention is a table made of ceramic for supporting a wafer in a semiconductor manufacturing apparatus. Typically, the ceramic heater according to the present invention can be a ceramic heater for a semiconductor deposition apparatus. Typical examples of a deposition apparatus include CVD (chemical vapor deposition) apparatuses (e.g., a thermal CVD apparatus, a plasma CVD apparatus, a photo CVD apparatus, and a MOCVD apparatus) and PVD (physical vapor deposition) apparatuses.

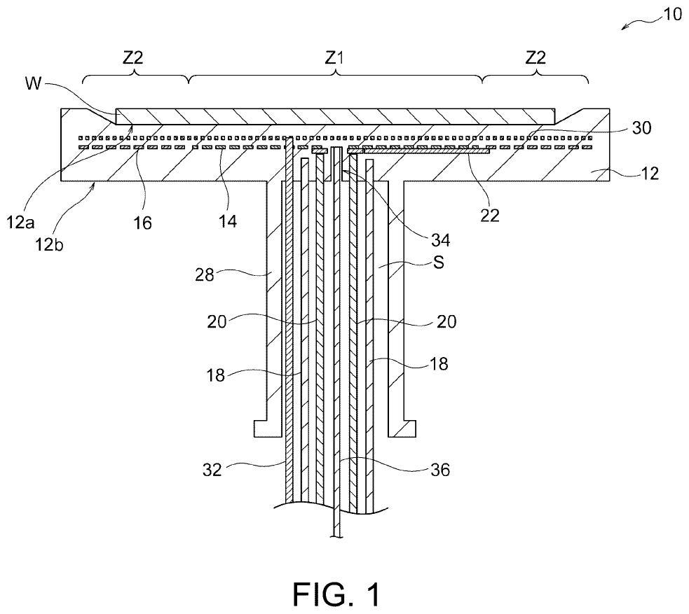

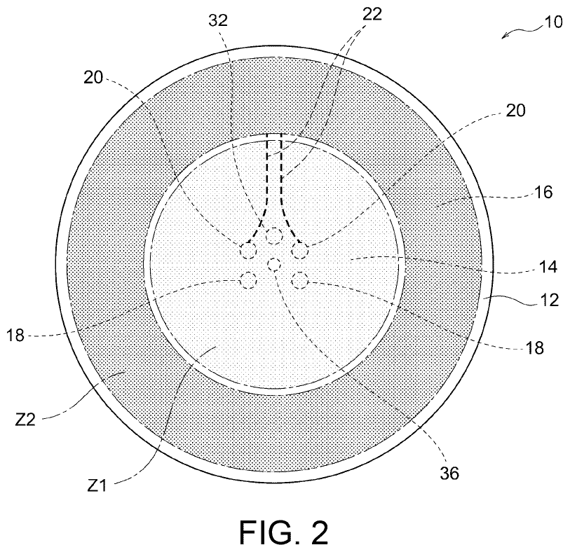

One aspect of the ceramic heater is shown in FIGS. 1 and 2. A ceramic heater 10 shown in FIGS. 1 and 2 includes a ceramic plate 12, an inner zone heater circuit 14, an outer zone heater circuit 16, and one pair of jumpers 22. The ceramic plate 12 is disk-shaped and has a first surface 12a on which a wafer W is to be placed and a second surface 12b opposite to the first surface 12a. The ceramic plate 12 includes an inner zone Z1 which is defined as a circular region within a predetermined distance from a center of the ceramic plate 12 and an outer zone Z2 defined as an annular region outside the inner zone Z1 when viewed in plan view. While the inner zone heater circuit 14 is embedded in the inner zone Z1 of the ceramic plate 12, the outer zone heater circuit 16 is embedded in the outer zone Z2 of the ceramic plate. The one pair of jumpers 22 is embedded in the inner zone Z1 of the ceramic plate 12 so as not to contact the inner zone heater circuit 14 and is electrically connected to the outer zone heater circuit 16. A percentage of a resistance value per jumper 22 to a resistance value of the outer zone heater circuit 16 is from 0.5 to 1.9%. Setting the percentage of the resistance value per jumper 22 to the resistance value of the outer zone heater circuit 16 within the range from 0.5 to 1.9%, as described above, makes breakage unlikely to occur at the time of manufacture or use, and allows achievement of not only desirable thermal uniformity but also a desirable temperature distribution profile when an inner zone/outer zone power ratio is changed.

As described earlier, a conventional multizone ceramic heater including a jumper may suffer breakage at the time of manufacture or use. Even if this is not the case, the conventional multizone ceramic heater may suffer the problem of the inability to obtain desirable thermal uniformity or the problem of the difficulty in achieving a desirable temperature distribution profile when an inner zone/outer zone power ratio is changed. For example, if a three-dimensional coil type resistance heating element is used, increase in jumper diameter as proposed in Patent Literature 1 increases a thermal stress generated at the time of manufacture or use to enhance breakage risk. In a case using a resistance heating element with a linear zigzag structure as well, increase in jumper diameter causes a rise in breakage risk, as in the case of the three-dimensional coil. Additionally, if an outer zone is set larger in size than an inner zone, change of an inner zone/outer zone power ratio of a two-zone heater due to, e.g., alteration of process conditions prevents achievement of a temperature distribution profile desired by a user (e.g., a desire to selectively or preferentially raise a temperature of an outer peripheral portion of the ceramic heater). The present invention successfully solves the above-described problems.

Although increase in a diameter of a jumper in the related art can make a resistance value of the jumper lower than a resistance value of an outer zone heater circuit, the increase enhances breakage risk due to a thermal stress at the time of manufacture or use to lead to difficulty in actual use. For this reason, to significantly enhance a heating element density in an outer zone heater circuit, attempts were made to (i) increase a coil winding diameter, reduce a coil wire diameter, and/or maximize the number of coil turns (reduce a coil pitch) in the case of a three-dimensional coil type resistance heating element, (ii) increase a maximum width of a linear zigzag structure, reduce a wire diameter of the linear zigzag structure, and/or maximize the number of zigzags (reduce a pitch) in the case of a resistance heating element with the linear zigzag structure, and (iii) reduce a printing width, reduce a printing thickness, and/or zigzag a printed pattern in the case of a printed pattern resistance heating element. The attempts allowed significant reduction in a ratio of a resistance value of a jumper to a resistance value of an outer zone heater circuit. This significantly suppressed relative heat generation in a jumper, which resulted in improvement of thermal uniformity (temperature uniformity) of the ceramic heater 10.

Specifically, the percentage of the resistance value per jumper 22 to the resistance value of the outer zone heater circuit 16 is from 0.5 to 1.9%, preferably from 0.5 to 1.1%, and more preferably from 0.5 to 0.9%. If the percentage is within one of the ranges, breakage is unlikely to occur at the time of manufacture or use, and not only desirable thermal uniformity but also a desirable temperature distribution profile when an inner zone/outer zone power ratio is changed can be more effectively achieved.

In terms of excellent thermal conductivity, high electrical insulation, thermal expansion characteristics close to silicon, and the like, a main portion (i.e., a ceramic base) other than embedded members, such as the inner zone heater circuit 14, the outer zone heater circuit 16, and the jumpers 22, of the ceramic plate 12 preferably contains aluminum nitride or aluminum oxide, more preferably aluminum nitride.

The ceramic plate 12 is disk-shaped. A shape in plan view of the disk-shaped ceramic plate 12 need not be a complete circular shape and may be, for example, an incomplete circular shape which is chipped like an orientation flat. The size of the ceramic plate 12 may be appropriately determined in accordance with a diameter of a wafer which is assumed to be used and is not particularly limited. If the ceramic plate 12 is circular, a diameter is typically from 150 to 450 mm. In the ceramic plate 12 for a 300-mm silicon wafer, the diameter is typically from 320 to 380 mm. A thickness of the ceramic plate 12 is typically from 10 to 25 mm.

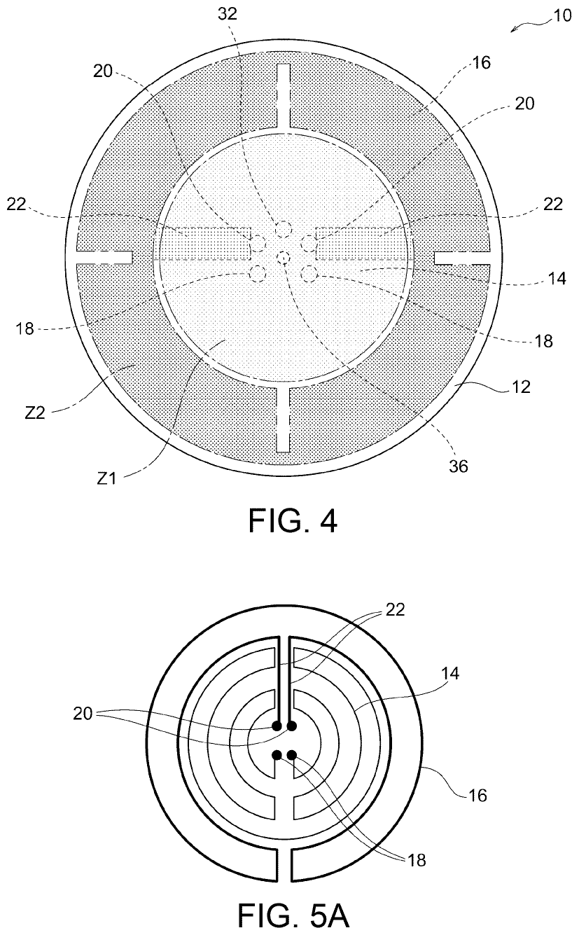

The ceramic plate 12 includes the inner zone Z1 and the outer zone Z2 when viewed in plan view. The inner zone Z1 is defined as a circular region within the predetermined distance from the center of the ceramic plate 12. The outer zone Z2 is defined as an annular region outside the inner zone Z1. The outer zone Z2 may be divided into a plurality of outer subzones (e.g., into from halves to quarters). In this case, the sum of resistance values of resistance heating elements embedded in the plurality of outer subzones is assumed to be the resistance value of the outer zone heater circuit 16. For example, the outer zone Z2 may be composed of a plurality of outer subzones which are obtained by dividing the outer zone Z2 into arc shapes (e.g., into from halves to quarters) (for example, the outer zone Z2 is divided into halves in FIG. 4). Alternatively, the outer zone Z2 may concentrically have two or more annular regions which do not overlap with each other and have different sizes. In this case, the outer zone Z2 at least has a first outer zone close to the inner zone Z1 and a second outer zone located outside the first outer zone. A third or subsequent outer zone may be present outside the second outer zone as needed.

The inner zone heater circuit 14 and the outer zone heater circuit 16 preferably include a resistance heating element in the form of at least one selected from the group consisting of a coil, a linear zigzag structure, a printed pattern, a ribbon, and a mesh. While the coil has a configuration in which a resistance heating wire is three-dimensionally wound, the linear zigzag structure has a configuration in which a resistance heating wire is two-dimensionally folded back alternately in opposite directions in a plane. Although the printed pattern is not particularly limited, the printed pattern typically has a pattern in which a strip-shaped line in a resistance heating element layer alternates travel in a straight line and flection (e.g., in a zigzag manner). For the inner zone heater circuit 14 and the outer zone heater circuit 16, resistance heating elements in the same form are preferably used in terms of ease of fabrication. Resistance heating elements in different forms, however, may be used. Each of the inner zone heater circuit 14 and the outer zone heater circuit 16 is preferably disposed in the form of a single continuous course when viewed in plan view. The form of a single continuous course can be every type of publicly known form, such as alternation of travel and turnback or a spiral shape.

The inner zone heater circuit 14 is embedded parallel to the first surface 12a in the inner zone Z1 of the ceramic plate 12. One pair of first feeding terminals 18 for feeding power to the inner zone heater circuit 14 is provided in a central portion of the inner zone Z1 of the ceramic plate 12. Preferably, the respective first feeding terminals 18 are connected to two ends of the inner zone heater circuit 14. Two or more pairs of first feeding terminals 18 may be present. The first feeding terminals 18 are rod-shaped, and the inner zone heater circuit 14 is connected to a heater power source (not shown) via the rod-shaped first feeding terminals 18.

In a preferred aspect of the present invention, the inner zone heater circuit 14 includes a resistance heating element in coil form. In this case, a coil winding diameter is preferably from 2.5 to 5.0 mm, more preferably from 2.5 to 4.0 mm, and further preferably from 3.0 to 3.5 mm. A coil wire diameter is preferably from 0.3 to 0.7 mm, more preferably from 0.4 to 0.6 mm, and further preferably from 0.4 to 0.5 mm. In another preferred aspect of the present invention, the inner zone heater circuit 14 includes a resistance heating element in the form of a linear zigzag structure. In this case, a maximum width of the linear zigzag structure is preferably from 5 to 15 mm, more preferably from 5 to 10 mm, and further preferably from 6 to 8 mm. Note that the maximum width of the linear zigzag structure is defined as a clearance between a line connecting vertexes on one side of the linear zigzag structure and a line connecting vertexes on the other side. A wire diameter of the linear zigzag structure is preferably from 0.3 to 0.7 mm, more preferably from 0.4 to 0.6 mm, and further preferably from 0.4 to 0.5 mm. In still another preferred aspect of the present invention, the inner zone heater circuit 14 includes a resistance heating element in the form of a printed pattern. In this case, a printing thickness of the printed pattern (a thickness of a resistance heating element layer) is preferably from 0.01 to 0.06 mm, more preferably from 0.01 to 0.04 mm, and further preferably from 0.015 to 0.03 mm.

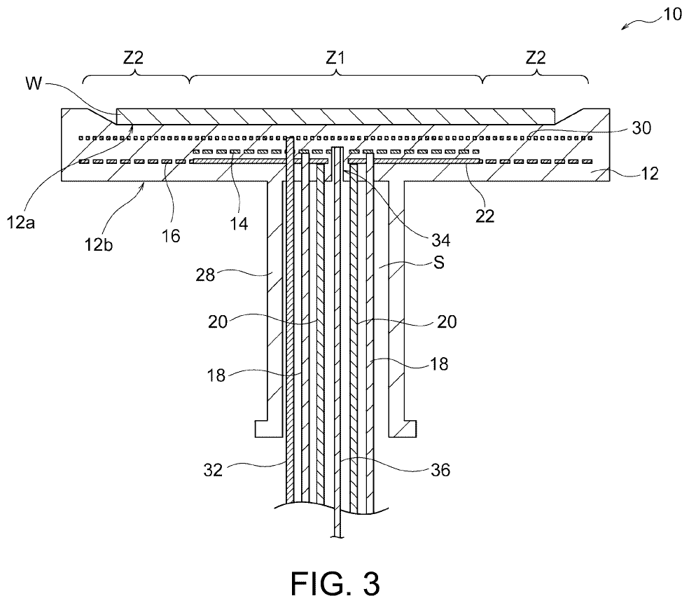

The outer zone heater circuit 16 is embedded parallel to the first surface 12a at the same depth position as or a depth position different from the inner zone heater circuit 14 in the outer zone Z2 of the ceramic plate 12. In a preferred aspect of the present invention, the outer zone heater circuit 16 can be embedded parallel to the first surface 12a at the same depth position as the inner zone heater circuit 14 in the outer zone Z2 of the ceramic plate 12, as shown in FIGS. 1 and 2. In another preferred aspect of the present invention, the outer zone heater circuit 16 can be embedded parallel to the first surface 12a at a depth position different from the inner zone heater circuit 14 in the outer zone Z2 of the ceramic plate 12, as shown in FIGS. 3 and 4. Although the inner zone heater circuit 14 is embedded above the outer zone heater circuit 16 (i.e., at a depth position close to the first surface 12a) in FIG. 3, the inner zone heater circuit 14 is not limited to this. Thus, the inner zone heater circuit 14 may be embedded below the outer zone heater circuit 16 (i.e., at a depth position closer to the second surface 12b). In either aspect, one pair of second feeding terminals 20 for feeding power to the outer zone heater circuit 16 via the jumpers 22 is provided in the central portion (but at positions different from the first feeding terminals 18) of the inner zone Z1 of the ceramic plate 12. Since the one pair of second feeding terminals 20 is arranged at positions separate from the outer zone heater circuit 16, the one pair of second feeding terminals 20 is electrically connected to the outer zone heater circuit 16 via the one pair of jumpers 22. Two or more pairs of second feeding terminals 20 may be present. The second feeding terminals 20 are rod-shaped, and the outer zone heater circuit 16 is connected to the heater power source (not shown) via the jumpers 22 and the rod-shaped second feeding terminals 20.

In a preferred aspect of the present invention, the outer zone heater circuit 16 includes a resistance heating element in coil form. In this case, a coil winding diameter is preferably from 2.5 to 5.0 mm, more preferably from 2.5 to 4.0 mm, and further preferably from 3.0 to 3.5 mm. A coil wire diameter is preferably from 0.3 to 0.7 mm, more preferably from 0.4 to 0.6 mm, and further preferably from 0.4 to 0.5 mm. In another preferred aspect of the present invention, the outer zone heater circuit 16 includes a resistance heating element in the form of a linear zigzag structure. In this case, a maximum width of the linear zigzag structure is preferably from 5 to 15 mm, more preferably from 5 to 10 mm, and further preferably from 6 to 8 mm. A wire diameter of the linear zigzag structure is preferably from 0.3 to 0.7 mm, more preferably from 0.4 to 0.6 mm, and further preferably from 0.4 to 0.5 mm. In still another preferred aspect of the present invention, the outer zone heater circuit 16 includes a resistance heating element in the form of a printed pattern. In this case, a printing thickness of the printed pattern (a thickness of a resistance heating element layer) is preferably from 0.01 to 0.06 mm, more preferably from 0.01 to 0.04 mm, and further preferably from 0.015 to 0.03 mm. In any aspect, if the resistance heating element has dimensions within the above-described ranges, a heating element density in the outer zone heater circuit is easier to significantly enhance, and a ratio of the resistance value of the jumper 22 to the resistance value of the outer zone heater circuit 16 can be effectively reduced. That is, the percentage of the resistance value per jumper 22 to the resistance value of the outer zone heater circuit 16 is more easily adjusted within the range from 0.5 to 1.9%. As a result, breakage is less likely to occur at the time of manufacture or use, and not only desirable thermal uniformity but also a desirable temperature distribution profile when an inner zone/outer zone power ratio is changed can be more effectively achieved.

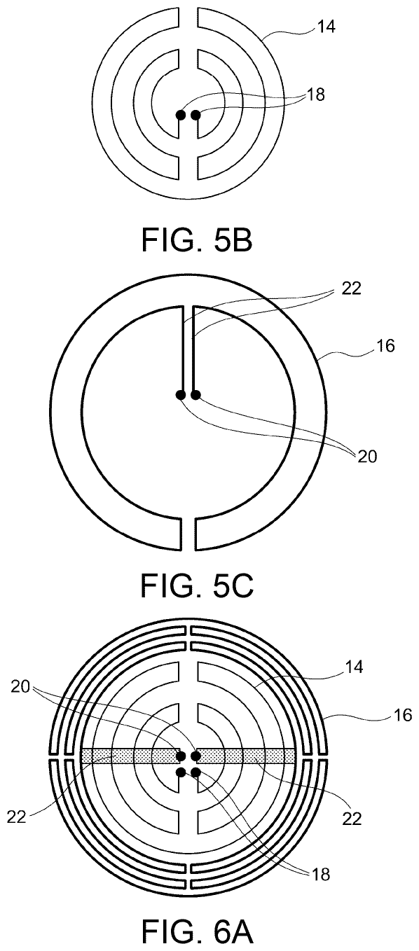

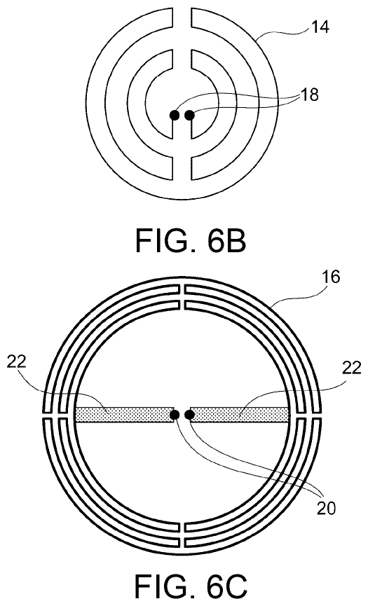

The outer zone heater circuit 16 may be either a series circuit or a parallel circuit. That is, the outer zone heater circuit 16 may be provided to start from one of the one pair of jumpers 22 in one direction and arrive at the other of the one pair of jumpers 22 through a single continuous course so as to form a series circuit (see, for example, FIGS. 5A and 5C (to be described later)). Alternatively, the outer zone heater circuit 16 may be provided to start from one of the one pair of jumpers 22 in two directions and arrive, for each start direction, at the other of the one pair of jumpers 22 through a single continuous course so as to form a parallel circuit (see, for example, FIGS. 6A and 6C (to be described later)). While the outer zone heater circuit 16 shown in FIG. 1 corresponds to the series circuit, the outer zone heater circuit 16 shown in FIG. 3 corresponds to the parallel circuit.

The one pair of jumpers 22 is embedded in the inner zone Z1 of the ceramic plate 12 so as not to contact the inner zone heater circuit 14 and is electrically connected to the outer zone heater circuit 16. The one pair of jumpers 22 can be embedded parallel to the first surface 12a at the same depth position as or a depth position different from the outer zone heater circuit 16. The one pair of jumpers 22 is separate from each other. While one jumper 22 electrically connects one of the second feeding terminals 20 and one end of the outer zone heater circuit 16, the other jumper 22 electrically connects the other of the second feeding terminals 20 and the other end of the outer zone heater circuit 16. Two or more pairs of jumpers 22 may be present.

The jumper 22 preferably includes a resistance heating element in the form of at least one selected from the group consisting of a wire, a printed pattern, and a ribbon. A specific form of the wire is not particularly limited, and typical examples of the specific form include a straight line, a curved line (e.g., an arc), and a combination of a straight line and a curved line (e.g., a straight line partially bent with a curvature). In a preferred aspect of the present invention, the jumper 22 is a linear resistance heating element (i.e., a resistance heating element wire). In this case, a wire diameter of the resistance heating element wire is preferably from 0.3 to 0.7 mm, more preferably from 0.4 to 0.7 mm, and further preferably from 0.5 to 0.7 mm. In another preferred aspect of the present invention, the jumper 22 is a printed pattern. In this case, a printing thickness of the printed pattern (a thickness of a resistance heating element layer) is preferably from 0.01 to 0.06 mm, more preferably from 0.02 to 0.05 mm, and further preferably from 0.025 to 0.04 mm.

Each of the one pair of jumpers 22 and the one pair of second feeding terminals 20 is preferably arranged symmetric with respect to a perpendicular bisector of a line segment connecting the one pair of second feeding terminals 20 when the ceramic plate 12 is viewed in plan view. This configuration allows equalization of feeding path lengths from the one pair of second feeding terminals 20 to the outer zone heater circuit 16 via the one pair of jumpers 22 and allows much easier achievement of satisfactory thermal uniformity.

The ceramic plate 12 may further include an RF electrode 30 and/or an ESC electrode. In this case, the RF electrode 30 and/or the ESC electrode is preferably embedded at a depth position, of the ceramic plate 12, closer to the first surface 12a than the inner zone heater circuit 14 and the jumpers 22 are. The RF electrode allows deposition by a plasma CVD process when a high-frequency wave is applied. The ESC electrode is an abbreviation for an electrostatic chuck (ESC) electrode and is also called an electrostatic electrode. The ESC electrode chucks a wafer placed on a surface of the ceramic plate 12 by a Johnsen-Rahbek force when a voltage is applied by the external power source. The ESC electrode is preferably a circular thin-layer electrode slightly smaller in diameter than the ceramic plate 12 and can be, for example, a mesh-like electrode obtained by reticularly weaving thin metal lines into sheet form. The ESC electrode can also be used as a plasma electrode. That is, the ESC electrode can also be used as an RF electrode by applying a high-frequency wave to the ESC electrode and can also perform deposition by the plasma CVD process. An RF terminal 32 for power feeding or an ESC terminal is connected to the RF electrode 30 or the ESC electrode. The RF terminal 32 or the ESC terminal is rod-shaped, and the RF electrode 30 or the ESC electrode is connected to the external power source (not shown) via the rod-shaped RF terminal 32 or the ESC terminal.

Optionally, a ceramic shaft 28 may be concentrically attached to the second surface 12b of the ceramic plate 12. The ceramic shaft 28 is a cylindrical member including an internal space S and can have the same configuration as a ceramic shaft which is adopted by a publicly known ceramic susceptor or ceramic heater. The internal space S is configured such that a terminal rod, such as the first feeding terminal 18, the second feeding terminal 20, or the RF terminal 32, passes therethrough. The ceramic shaft 28 is preferably made of the same ceramic material as the ceramic plate 12. Thus, the ceramic shaft 28 preferably contains aluminum nitride or aluminum oxide, more preferably aluminum nitride. An upper end face of the ceramic shaft 28 is preferably bonded to the second surface 12b of the ceramic plate 12 by solid-phase bonding or diffusion bonding. An outer diameter of the ceramic shaft 28 is not particularly limited and is preferably from 40 to 60 mm. An inner diameter of the ceramic shaft 28 (a diameter of the internal space S) is also not particularly limited and is preferably from 33 to 55 mm.

### EXAMPLES

The present invention will be more specifically described taking the examples below.

Note that the present invention is not limited to the examples.

### Examples 1 to 9 and 12

### (1) Fabrication of Ceramic Heater

A ceramic heater 10 having a structure as shown in FIGS. 1 and 2 was fabricated using the constituent members shown below by a publicly known procedure except firing conditions.

### <Constituent Member and Specification Thereof>

Ceramic plate 12: a disk-shaped aluminum nitride sintered body (having a diameter of 330 mm and a thickness of 20 mm) (one with an inner zone heater circuit 14, an outer zone heater circuit 16, jumpers 22, and an RF electrode 30 embedded therein)
Ceramic shaft 28: a cylindrical aluminum nitride sintered body (having a height of 172 mm, an outer diameter of 47 mm, and an inner diameter of 36 mm)
Inner zone Z1: a circular region having a diameter of 216 mm located at the center of the ceramic plate 12
Outer zone Z2: an annular region outside the inner zone Z1 in the ceramic plate 12
Inner zone heater circuit 14: a resistance heating element in the shape of a three-dimensional coil (corresponding to Examples 1 to 5, 8, and 9, made of molybdenum, and having a winding diameter and a wire diameter as shown in Table 1) or a resistance heating element with a linear zigzag structure (corresponding to Examples 6 and 7, made of molybdenum, and having a wire diameter and a maximum heating element width (a maximum width of the zigzag structure) as shown in Table 1) which was embedded at a position having a depth of 6.5 mm from a first surface 12a in the inner zone Z1 in accordance with a circuit pattern shown in FIGS. 5A and 5B
Outer zone heater circuit 16: a resistance heating element in the shape of a three-dimensional coil (corresponding to Examples 1 to 5, 8, and 9, made of molybdenum, and having a winding diameter and a wire diameter as shown in Table 1) or a resistance heating element with a linear zigzag structure (corresponding to Examples 6 and 7, made of molybdenum, and having a wire diameter and a maximum heating element width (a maximum width of the zigzag structure) as shown in Table 1) which was embedded at a position having a depth of 6.5 mm from the first surface 12a in the outer zone Z2 in accordance with a circuit pattern shown in FIGS. 5A and 5C
Jumpers 22: one bilaterally symmetric pair of generally linear resistance heating wires (made of molybdenum and having a wire diameter of 0.7 mm) which were embedded at positions having a depth of 6.5 mm from the first surface 12a in the inner zone Z1 in accordance with the circuit pattern shown in FIGS. 5A and 5C (Although the jumpers 22 are schematically drawn as straight lines in FIGS. 5A and 5C, the jumpers 22 actually had generally linear shapes partially including a curved portion, as shown in FIG. 2)
RF electrode 30: an electrode layer made of molybdenum which was embedded at a position having a depth of 1.0 mm from the first surface 12a of the ceramic plate 12
First feeding terminals 18: two terminal rods made of nickel
Second feeding terminals 20: two terminal rods made of nickel
RF terminal 32: one terminal rod made of nickel

The ceramic plate 12 with the inner zone heater circuit 14, the outer zone heater circuit 16, the jumpers 22, and the RF electrode 30 embedded therein was fabricated by the procedure below. Aluminum nitride powder was first press-molded to obtain a first aluminum nitride green compact. Aluminum nitride powder, the inner zone heater circuit 14, the outer zone heater circuit 16, and the jumpers 22 were arranged on the obtained first aluminum nitride green compact in accordance with the circuit patterns shown in FIGS. 5A to 5C and were press-molded to obtain a second aluminum nitride green compact with the inner zone heater circuit 14, the outer zone heater circuit 16, and the jumpers 22 embedded therein. Aluminum nitride powder and the RF electrode 30 were arranged on the obtained second aluminum nitride green compact and were press-molded to obtain a third aluminum nitride green compact with the RF electrode 30 further embedded therein. In this manner, a press-molded body composed of an aluminum nitride green compact with the inner zone heater circuit 14, the outer zone heater circuit 16, the jumpers 22, and the RF electrode 30 embedded therein, as shown in FIG. 2, was obtained. The obtained press-molded body (multilayer body) was fired under a nitrogen atmosphere under the firing conditions below:
Maximum temperature: 1810° C.
Holding time at maximum temperature: 5 hours
Rate of temperature rise: changed within the range from 10 to 120° C./min (a rate range including individual rates of temperature rise at a plurality of stages of temperature rise)
Firing pressure: 90 kg/cm² to obtain the ceramic plate 12 with the inner zone heater circuit 14, the outer zone heater circuit 16, the jumpers 22, and the RF electrode 30 embedded therein.

### (2) Assessment

Various types of assessments were made on obtained ceramic heaters.

### <Jumper/Outer Heater Resistance Ratio>

At room temperature, a resistance value of the outer zone heater circuit 16 and a resistance value per jumper 22 were measured. The resistance value of the outer zone heater circuit 16 was measured by connecting a tester based on the four-terminal method to two ends of the outer zone heater circuit 16. The resistance value per jumper 22 was obtained by performing measurements by connecting the tester based on the four-terminal method to two ends of each of the one pair of (i.e., two) jumpers 22 and calculating an average value of two obtained resistance values. A percentage of a resistance value per jumper to a resistance value of an outer zone heater circuit (hereinafter referred to as a jumper/outer heater resistance ratio) was obtained by dividing the resistance value per jumper 22 by the resistance value of the outer zone heater circuit 16 and multiplying the quotient by 100. Results were as shown in Table 1.

### <Thermal Uniformity>

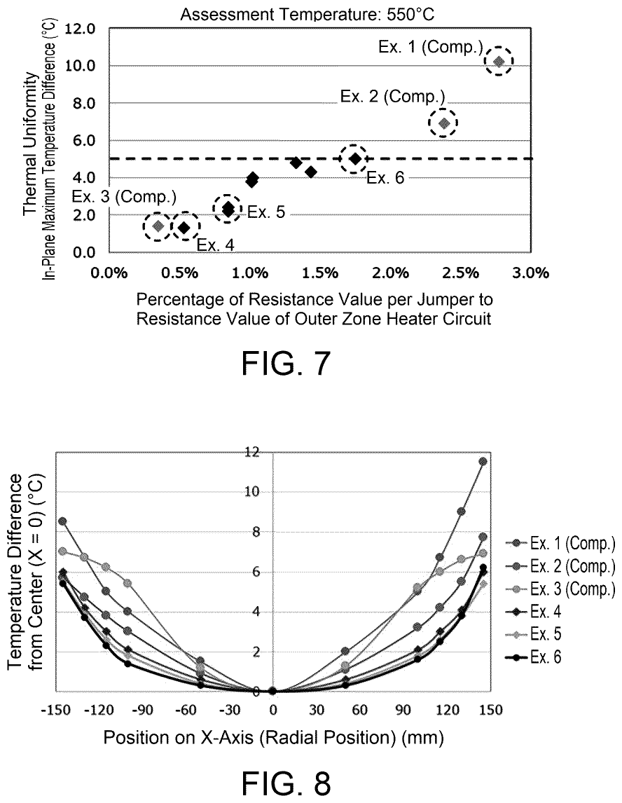

The ceramic heater 10 was installed in a chamber of a deposition apparatus. A vacuum was drawn on the chamber, N₂ gas was introduced into the chamber, and an N₂ gas pressure in the chamber was set to 5 Torr. The ceramic heater 10 was heated to a set temperature of 550° C. by feeding power to the inner zone heater circuit 14 and the outer zone heater circuit 16 via the first feeding terminals 18, the second feeding terminals 20, and the jumpers 22. At that time, a ratio between power to be fed to the outer zone heater circuit 16 and power to be fed to the inner zone heater circuit 14 was finely adjusted using 1:1 as a reference so as to achieve a most even temperature distribution. At the set temperature, a temperature distribution at the first surface 12a of the ceramic plate 12 was measured by an infrared camera. A difference between a maximum temperature and a minimum temperature in a plane (i.e., an in-plane maximum temperature difference) was obtained as an indicator of thermal uniformity on the basis of an obtained temperature distribution map. Results were as shown in Table 1. FIG. 7 shows a relationship between an obtained in-plane maximum temperature difference and a jumper/outer heater resistance ratio. Note that, for Example 12, breakage of the ceramic heater 10 occurred at the time of assessment, and that thermal uniformity and a temperature profile (to be described later) could not be assessed.

### <Temperature Profile When Outer/Inner Power Ratio Is Changed>

The ceramic heater 10 was heated to a set temperature of 550° C. (a temperature to be measured by a thermocouple 36 in the inner zone Z1) in the same manner as the above-described thermal uniformity assessment except that power from 1.3 to 1.5 times the inner zone heater circuit 14 was fed to the outer zone heater circuit 16 (i.e., an outer/inner power ratio was changed) to prompt the outer zone Z2 to preferentially rise in temperature. At the set temperature, a temperature distribution at the first surface 12a of the ceramic plate 12 was measured by the infrared camera. In an obtained temperature distribution map, a given straight line through a center of the ceramic plate 12 was defined as an X-axis, and the center of the ceramic plate 12 was set as an X-coordinate axis reference point (X=0 mm). Temperature differences as amounts of increase in temperature were obtained by reading, from the temperature distribution map, temperatures at various types of positions (radial positions) including the inner zone Z1 and the outer zone Z2 on the X-axis of the ceramic plate 12 and subtracting a center temperature at X=0 mm from each of the read temperatures at the various types of positions. A temperature profile was obtained by plotting the obtained temperature differences at the positions in relation to the positions on the X-axis and setting an approximate curve. Whether the obtained temperature profile was good or poor was assessed by the criteria below. Results were as shown in Table 1 and FIG. 8.

### [Assessment Criteria]

Good: a temperature profile which is generally bilaterally symmetric and in which a temperature rises with a higher temperature gradient (the slope of a tangent to the approximate curve of the temperature profile) toward an outer periphery while an excessive temperature rise is suppressed at an intermediate portion (a region where an absolute value of X is from about 60 to 130 mm) of the ceramic plate 12
Poor: a temperature profile which does not fit the above-described criteria for good (i.e., one which is bilaterally asymmetric and/or in which an excessive temperature rise (e.g., a higher temperature gradient than near an outer periphery) is seen at an intermediate portion)

### Examples 10 and 11

### (1) Fabrication of Ceramic Heater

A ceramic heater 10 having a structure as shown in FIGS. 3 and 4 was fabricated using the constituent members shown below by a publicly known procedure except firing conditions.

### <Constituent Member and Specification Thereof>

Ceramic plate 12: a disk-shaped aluminum nitride sintered body (having a diameter of 330 mm and a thickness of 20 mm) (one with an inner zone heater circuit 14, an outer zone heater circuit 16, jumpers 22, and an RF electrode 30 embedded therein)
Ceramic shaft 28: a cylindrical aluminum nitride sintered body (having a height of 172 mm, an outer diameter of 60 mm, and an inner diameter of 51 mm)
Inner zone Z1: a circular region having a diameter of 216 mm located at the center of the ceramic plate 12
Outer zone Z2: an annular region outside the inner zone Z1 in the ceramic plate 12
Inner zone heater circuit 14: a printed pattern (having a zigzag shape and a printing thickness as shown in Table 1) composed of a resistance heating element which was embedded at a position having a depth of 6.5 mm from a first surface 12a in the inner zone Z1 in accordance with a circuit pattern shown in FIGS. 6A and 6B
Outer zone heater circuit 16: a printed pattern as a parallel circuit (having a zigzag shape and a printing thickness as shown in Table 1) composed of a resistance heating element which was embedded at a position having a depth of 11 mm from the first surface 12a in the outer zone Z2 in accordance with a circuit pattern shown in FIGS. 6A and 6C
Jumpers 22: a bilaterally symmetric printed pattern (having a printing thickness of 0.03 mm) composed of a resistance heating element which was embedded in a region shown in FIGS. 6A and 6C at a position having a depth of 11 mm from the first surface 12a in the inner zone Z1
Resistance heating element: a tungsten carbide-titanium nitride composite material (common to the inner zone heater circuit 14, the outer zone heater circuit 16, and the jumpers 22)
RF electrode 30: an electrode layer made of molybdenum which was embedded at a position having a depth of 1.0 mm from the first surface 12a of the ceramic plate 12
First feeding terminals 18: two terminal rods made of nickel
Second feeding terminals 20: two terminal rods made of nickel
RF terminal 32: one terminal rod made of nickel

The ceramic plate 12 with the inner zone heater circuit 14, the outer zone heater circuit 16, the jumpers 22, and the RF electrode 30 embedded therein was fabricated by the procedure below. First, two disk-shaped aluminum nitride sintered bodies were provided. The inner zone heater circuit 14 was printed on one aluminum nitride sintered body in accordance with the circuit pattern shown in FIGS. 6A and 6B. The outer zone heater circuit 16 and the jumpers 22 were printed on the other aluminum nitride sintered body in accordance with the circuit pattern shown in FIGS. 6A and 6C.

Aluminum nitride powder and the RF electrode 30 were press-molded to obtain an aluminum nitride green compact with the RF electrode 30 embedded therein. The aluminum nitride green compact and the aluminum nitride sintered bodies with the printed patterns were stacked so as to have a layer structure shown in FIG. 4, and were press-molded. An obtained press-molded body (multilayer body) was fired under a nitrogen atmosphere under the firing conditions below:
Maximum temperature: 1810° C.
Holding time at maximum temperature: 5 hours
Rate of temperature rise: changed within the range from 10 to 120° C./min (a rate range including individual rates of temperature rise at a plurality of stages of temperature rise)
Firing pressure: 90 kg/cm² to obtain the ceramic plate 12 with the inner zone heater circuit 14, the outer zone heater circuit 16, the jumpers 22, and the RF electrode 30 embedded therein.

### (2) Assessment

The same assessments as Example 1 were made on obtained ceramic heaters.

TABLE 1

| | | Jumper | | Outer Zone Heater Circuit | | |
|---|---|---|---|---|---|---|
| | | Jumper/Outer | Wire Diameter | Coil | Wire Diameter | |
| | Resistance | Heater | D or Printing | Winding | D or Printing | Heating Element |
| | Heating | Resistance | Thickness T | Diameter | Thickness T | Maximum Width |
| | Element | Ratio (%) | (mm) | (mm) | (mm) | (mm) |
| Ex. 1* | coil | 2.8 | D: 0.5 | 3.0 | D: 0.5 | — |
| Ex. 2* | coil | 2.4 | D: 0.5 | 3.0 | D: 0.5 | — |
| Ex. 3* | coil | 0.3 | D: 0.7 | 3.0 | D: 0.5 | — |
| Ex. 4 | coil | 0.5 | D: 0.7 | 5.0 | D: 0.4 | — |
| Ex. 5 | coil | 0.9 | D: 0.7 | 4.0 | D: 0.3 | — |
| Ex. 6 | linear | 1.9 | D: 0.7 | — | D: 0.5 | 5 to 10 |
| | zigzag | | | | | |
| Ex. 7 | linear | 0.9 | D: 0.7 | — | D: 0.4 | 5 to 15 |
| | zigzag | | | | | |
| Ex. 8 | coil | 1.0 | D: 0.7 | 4.0 | D: 0.5 | — |
| Ex. 9 | coil | 1.4 | D: 0.7 | 3.0 | D: 0.4 | — |
| Ex. 10 | printed | 1.0 | T: 0.025 | — | T: 0.015 | — |
| | pattern | | | | | |
| Ex. 11 | printed | 1.3 | T: 0.030 | — | T: 0.02 | — |
| | pattern | | | | | |
| Ex. 12* | coil | 0.4 | D: 1.0 | 4.0 | D: 0.5 | — |

| | | | | Thermal | |
|---|---|---|---|---|---|
| | Inner Zone Heater Circuit | | | Uniformity: | |
| | | | Heating | In-Plane | Temperature |
| | Coil | Wire Diameter | Element | Maximum | Profile When |
| | Winding | D or Printing | Maximum | Temperature | Outer/Inner |
| | Diameter | Thickness T | Width | Difference | Power Ratio |
| | (mm) | (mm) | (mm) | (° C.) | Is Changed |
| Ex. 1* | 3.0 | D: 0.5 | — | 10.2 | poor |
| Ex. 2* | 3.0 | D: 0.5 | — | 6.9 | poor |
| Ex. 3* | 3.0 | D: 0.5 | — | 1.4 | poor |
| Ex. 4 | 3.0 | D: 0.5 | — | 1.3 | good |
| Ex. 5 | 3.0 | D: 0.5 | — | 2.2 | good |
| Ex. 6 | — | D: 0.5 | 5 to 10 | 5.0 | good |
| Ex. 7 | — | D: 0.5 | 5 to 15 | 2.4 | good |
| Ex. 8 | 3.0 | D: 0.5 | — | 3.8 | good |
| Ex. 9 | 3.0 | D: 0.5 | — | 4.3 | good |
| Ex. 10 | — | T: 0.015 | — | 4.0 | good |
| Ex. 11 | — | T: 0.02 | — | 4.8 | good |

| | | | | |
|---|---|---|---|---|
| Ex. 12* | 3.0 | D: 0.5 | — | breakage at time |
| | | | | of manufacture |
| | | | | or assessment |

*represents a comparative example.

Note that, aside from the above-described examples, an attempt was made to fabricate a ceramic heater using coils made of molybdenum having a wire diameter of 0.2 mm as the inner zone heater circuit 14 and the outer zone heater circuit 16. Since the coils broke during fabrication and were highly deformed, the coils could not be adopted.

The following can be seen from results shown in Table 1 and FIGS. 7 and 8. Examples 1 and 2 (comparative) are each a comparative example having a jumper/outer heater resistance ratio above 2%. Each example had an in-plane maximum temperature difference above 5° C. at an assessment temperature of 550° C. and was inferior in thermal uniformity. When an outer/inner power ratio was changed to 1.4, an undesirable temperature profile inferior in bilateral symmetry was obtained, as shown in FIG. 8. Example 3 (comparative) is a comparative example having a jumper/outer heater resistance ratio as low as 0.3% and exhibited satisfactory thermal uniformity (an in-plane maximum temperature difference of 5.0° C. or less). When an outer/inner power ratio was changed to 1.4, an undesirable temperature profile in which an excessive temperature rise (a higher temperature gradient than near an outer periphery) was seen at an intermediate portion (a region where an absolute value of X was from about 60 to 130 mm) rather than at an outer peripheral portion was obtained, as shown in FIG. 8. Examples 4 to 11 are each an example having a jumper/outer heater resistance ratio within the range from 0.5 to 1.9%, and achieved satisfactory thermal uniformity (an in-plane maximum temperature difference of 5.0° C. or less) and a desirable temperature profile when a power ratio was changed. That is, as shown in FIG. 8, the temperature profile when the power ratio was changed was a desirable profile which was bilaterally symmetric and in which a temperature rose with a higher temperature gradient toward an outer periphery while an excessive temperature rise was suppressed at an intermediate portion (a region where an absolute value of X was from about 60 to 130 mm) of the ceramic plate 12. The ceramic heater industry often requires ceramic heaters which exhibit not only satisfactory thermal uniformity but also a temperature profile in which a temperature rises preferentially at an outer peripheral portion. The ceramic heaters according to Example 4 to 11 can be said to respond sufficiently to such needs.

What is claimed is:

1. A ceramic heater comprising:
a disk-shaped ceramic plate having a first surface on which a wafer is to be placed and a second surface opposite to the first surface, the ceramic plate including an inner zone defined as a circular region within a predetermined distance from a center of the ceramic plate and an outer zone defined as an annular region outside the inner zone when the ceramic plate is viewed in plan view;
an inner zone heater circuit embedded in the inner zone of the ceramic plate;
an outer zone heater circuit embedded in the outer zone of the ceramic plate; and
one pair of jumpers which are embedded in the inner zone of the ceramic plate so as not to contact the inner zone heater circuit and are electrically connected to the outer zone heater circuit,
wherein a percentage of a resistance value per the jumper to a resistance value of the outer zone heater circuit is from 0.5 to 1.9%.

2. The ceramic heater according to claim 1, wherein the inner zone heater circuit and the outer zone heater circuit include a resistance heating element in the form of at least one selected from the group consisting of a coil, a linear zigzag structure, a printed pattern, a ribbon, and a mesh.

3. The ceramic heater according to claim 2, wherein the outer zone heater circuit includes a resistance heating element in a coil form having a winding diameter of from 2.5 to 5.0 mm and a wire diameter of from 0.3 to 0.7 mm.

4. The ceramic heater according to claim 2, wherein the outer zone heater circuit includes a resistance heating element in the form of a linear zigzag structure having a maximum width of from 5 to 15 mm and a wire diameter of from 0.3 to 0.7 mm.

5. The ceramic heater according to claim 1, wherein the jumpers include a resistance heating element in the form of at least one selected from the group consisting of a wire, a printed pattern, and a ribbon.

6. The ceramic heater according to claim 1, wherein the outer zone is divided into a plurality of outer subzones, and a sum of resistance values of the resistance heating element embedded in the plurality of outer subzones is regarded as the resistance value of the outer zone heater circuit.

7. The ceramic heater according to claim 1, wherein the ceramic plate contains aluminum nitride or aluminum oxide.

8. The ceramic heater according to claim 1, further comprising:
one pair of first feeding terminals for feeding power to the inner zone heater circuit which are provided in a central portion of the inner zone of the ceramic plate; and
one pair of second feeding terminals for feeding power to the outer zone heater circuit via the jumpers which are provided in the central portion of the inner zone of the ceramic plate.

9. The ceramic heater according to claim 1, further comprising an internal electrode which is an RF electrode and/or an ESC electrode in the ceramic plate.

10. The ceramic heater according to claim 1, further comprising a cylindrical ceramic shaft which is concentrically attached to the second surface of the ceramic plate and includes an internal space.
